(19) United States
(12) Patent Application Publication
(10) Pub. No.: US 2020/0013592 A1
(43) Pub. Date: Jan. 9, 2020

(54) METHODS AND APPARATUS FOR LINEAR SCAN PHYSICAL VAPOR DEPOSITION WITH REDUCED CHAMBER FOOTPRINT

(71) Applicant: APPLIED MATERIALS, INC., Santa Clara, CA (US)

(72) Inventors: John Joseph Mazzocco, San Jose, CA (US); Ilya Lavitsky, Santa Clara, CA (US)

(21) Appl. No.: 16/459,719

(22) Filed: Jul. 2, 2019

Related U.S. Application Data
(60) Provisional application No. 62/694,940, filed on Jul. 6, 2018.

(51) Int. Cl. H01J 37/32; C23C 14/50; C23C 14/34; C23C 14/54; H01J 37/34; H01L 21/02

(52) U.S. Cl. CPC H01J 37/32651; C23C 14/505; C23C 14/3464; H01L 21/02266; H01J 37/32513; H01J 37/3447; C23C 14/54

(57) ABSTRACT

Apparatus and method for physical vapor deposition (PVD) are provided. The apparatus can include a linear PVD source to provide a stream of material flux comprising material to be deposited on a substrate; a substrate support having a support surface to support the substrate at a non-perpendicular angle to the stream of material flux, wherein the substrate support and linear PVD source are movable with respect to each other along an axis that is parallel to a plane of the support surface of the substrate support sufficiently to cause the stream of material flux to move completely over a surface of the substrate disposed on the substrate support during operation; and a selectively sealable aperture disposed between the linear PVD source and the substrate support, the selectively sealable aperture including two movable shields that are independently movable and configured to control a size and location of the selectively sealable aperture.

### CROSS-REFERENCE TO RELATED APPLICATIONS

This application claims benefit of U.S. Provisional Patent Application Ser. No. 62/694,940, filed Jul. 6, 2018 which is herein incorporated by reference in its entirety.

### FIELD

Embodiments of the present disclosure generally relate to substrate processing equipment, and more particularly, to methods and apparatus for depositing materials via physical vapor deposition.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventors have observed that with the drive to produce equipment to deposit more uniformly, certain applications may not be adequately served where purposeful deposition is required that is not symmetric or uniform with respect to the given structures being fabricated on a substrate.

Accordingly, the inventors have provided improved methods and apparatus for depositing materials via physical vapor deposition.

### SUMMARY

Methods and apparatus for physical vapor deposition are provided herein. In some embodiments, an apparatus for physical vapor deposition (PVD) can include a linear PVD source to provide a stream of material flux comprising material to be deposited on a substrate; a substrate support having a support surface to support the substrate at a non-perpendicular angle to the stream of material flux, wherein the substrate support and linear PVD source are movable with respect to each other along an axis that is parallel to a plane of the support surface of the substrate support sufficiently to cause the stream of material flux to move completely over a surface of the substrate disposed on the substrate support during operation; and a selectively sealable aperture disposed between the linear PVD source and the substrate support, the selectively sealable aperture including two movable shields that are independently movable and configured to control a size and location of the selectively sealable aperture.

In some embodiments, an apparatus for physical vapor deposition (PVD) can include a linear PVD source having a first target and a second target, each configured to provide corresponding first and second streams of material flux comprising material to be deposited on a substrate; a substrate support having a support surface to support the substrate at a non-perpendicular angle to the first and second streams of material flux, wherein the substrate support and the linear PVD source are movable with respect to each other along an axis that is parallel to a plane of the support surface of the substrate support sufficiently to cause the first and second streams of material flux to move completely over a surface of the substrate disposed on the substrate support during operation; and a selectively sealable aperture disposed between the linear PVD source and the substrate support, the selectively sealable aperture including two movable shields that are independently movable and configured to control a size and location of the selectively sealable aperture.

In some embodiments, a method for depositing material on a substrate can include directing a stream of material flux toward a selectively sealable aperture in a deposition chamber, wherein the selectively sealable aperture includes two movable shields in an initially closed position; moving a substrate support within the deposition chamber to perform a linear scan of the substrate disposed on the substrate support through the stream of material flux; moving a first shield of the two movable shields in a same direction and at a same time as the substrate to open the selectively sealable aperture and allow the stream of material flux to enter the deposition chamber and impinge upon the substrate; and moving a second shield of the two movable shields in the same direction and at the same time as the substrate to close the selectively sealable aperture upon completion of the linear scan.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic side view of an apparatus for physical vapor deposition in accordance with at least some embodiments of the present disclosure.

FIGS. 2A-2B respectively depict schematic top and isometric cross-sectional views of a substrate support and deposition structure of an apparatus for physical vapor deposition in accordance with at least some embodiments of the present disclosure.

FIG. 3 is a flow chart of a method for depositing a layer of material on a substrate in accordance with at least some embodiments of the present disclosure.

FIGS. 4A-4E respectively depict stages of operation of the apparatus during the method of FIG. 3 in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for physical vapor deposition (PVD) are provided herein. Embodiments of the disclosed methods and apparatus advantageously enable uniform angular deposition of materials on a substrate. In some applications, deposited materials are asymmetric or angular with respect to a given feature on a substrate, but can be relatively uniform within all features across the substrate. In some applications, deposited materials are symmetric with respect to a given feature on a substrate as well as relatively uniform within all features across the substrate, but possess a deposition profile not easily obtainable, if at all, using conventional physical vapor deposition techniques. Embodiments of the disclosed methods and apparatus advantageously enable new applications or opportunities for selective PVD of materials, thus further enabling new markets and capabilities.

In addition, embodiments of the disclosed methods and apparatus of the present disclosure advantageously provide a chamber footprint that is about 30-50% smaller in the dimension that is aligned to a scan motion of the substrate support, as described in more detail below. The decrease in footprint not only allows the chamber to better fit current mainframe designs, but also provides benefit to users through smaller systems having equivalent throughput and cost.

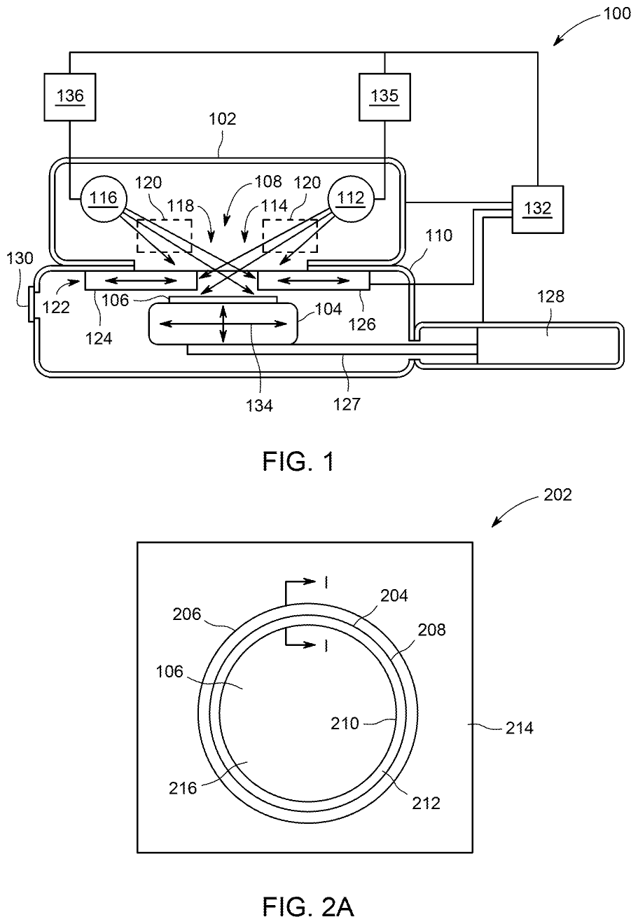

FIG. 1 is a schematic side view of an apparatus 100 for PVD in accordance with at least some embodiments of the present disclosure. Specifically, FIG. 1 schematically depicts an apparatus 100 for PVD of materials on a substrate at an angle to the generally planar surface of the substrate. The apparatus 100 generally includes a linear PVD source 102 and a substrate support 104 for supporting a substrate 106. The linear PVD source 102 is configured to provide a directed stream of material flux (stream 108 as depicted in FIG. 1) from the source toward the substrate support 104 (and any substrate 106 disposed on the substrate support 104). The substrate support 104 has a support surface to support the substrate 106 such that a working surface of the substrate 106 to be deposited on is exposed to the directed stream 108 of material flux.

The stream 108 of material flux provided by the linear PVD source 102 has a linear elongate axis corresponding to a width of the stream 108 of material flux (e.g., the stream 108 of material flux) is narrower in a dimension perpendicular to the elongate axis in the plane of the support surface or substrate positioned thereon). The width of the stream 108 of material flux is greater than that of the substrate support 104 (or at least greater than a substrate 106 disposed on the substrate support 104), measured at a position corresponding to the support surface or substrate 106 position.

The substrate support 104 and the linear PVD source 102 are configured to move linearly with respect to each other along an axis parallel to a plane of the support surface of the substrate support 104 (e.g., parallel to the plane of a substrate supported on the substrate support 104), as indicated by arrows 134. The relative motion can be accomplished by moving either or both of the linear PVD source 102 or the substrate support 104. In some embodiments, the linear PVD source 102 may be fixed and the substrate support 104 can be configured to move. In some embodiments, the substrate support 104 may be configured to move closer to or further from the linear PVD source 102 (for example, in a direction normal to the plane of the support surface). Optionally, the substrate support 104 may additionally be configured to rotate (for example, within the plane of the support surface).

The linear PVD source 102 includes a target of source material to be sputter deposited on the substrate. In some embodiments, the source material can be, for example, a metal, such as titanium (Ti), or the like, suitable for depositing Ti or titanium nitride (TiN) on the substrate 106. In some embodiments, the target material can be, for example, silicon, or a silicon-containing compound, suitable for depositing silicon (Si), silicon nitride (SiN), silicon oxynitride (SiON), or the like on the substrate 106. Other materials may suitably be used as well in accordance with the teachings provided herein. In general, the target material can be any material typically used in thin film fabrication via PVD.

As depicted in FIG. 1, the linear PVD source 102 may include a chamber or housing having an interior volume. A target 112 of source material to be sputtered is disposed within the housing. The target 112 is generally elongate and can be, for example, cylindrical or rectangular. For example, the target 112 depicted in FIG. 1 is cylindrical. However, the target 112 can also be a rectangular target having, for example, a planar rectangular face of target material to be sputtered. The target 112 size can vary depending upon the size of the substrate 106 and the configuration of the processing chamber. For example, for processing a 300 mm diameter semiconductor wafer, the target 112 can be between about 100 to about 200 mm in width or diameter, and can have a length of about 400 to about 800 mm. The target 112 can be stationary or movable, including rotatable along the elongate axis of the target 112.

The linear PVD source 102 further includes, or is coupled to, a power source to provide suitable power for forming a plasma proximate the target material and for sputtering atoms off of the target material. The power source can be either or both of a DC, which can be pulsed-DC, or an RF power source. In the embodiment depicted in FIG. 1, the target 112 is coupled to a power source 135. A gas supply (not shown) may be coupled to the interior volume of the housing to provide a gas, such as an inert gas (e.g., argon) or a reactive gas (e.g., oxygen (O₂), nitrogen (N₂), etc.) suitable for forming a plasma within the interior volume when sputtering material from the target 112 (creating the stream 108 of material flux). The linear PVD source 102 is coupled to a deposition chamber 110 containing the substrate support 104. A vacuum pump can be coupled to an exhaust port (not shown) in at least one of the housing of the linear PVD source 102 or the deposition chamber 110 to control the pressure during processing.

Unlike an ion beam or other ion source, the linear PVD source 102 is configured to provide mostly neutrals and few ions of the target material. As such, a plasma may be formed having a sufficiently low density to avoid ionizing too many of the sputtered atoms of target material. For example, for a 300 mm diameter wafer as the substrate 106, about 1 to about 20 kW of DC or RF power may be provided. The power or power density applied can be scaled for other size substrates. In addition, other parameters may be controlled to assist in providing mostly neutrals in the stream 108 of material flux. For example, the pressure may be controlled to be sufficiently low so that the mean free path is longer than the general dimensions of an opening of the linear PVD source 102 through which the stream of material flux passes toward the substrate support 104 (as discussed in more detail below). In some embodiments, the pressure may be controlled to be about 0.5 to about 5 millitorr.

In some embodiments, the linear PVD source 102 can include two targets (e.g., first target 112 and second target 116 depicted in FIG. 1) Each target can be disposed in a position such that the stream 108 of material flux includes a first stream 114 of material flux (from the first target 112) traveling in a first direction and a second stream 118 of material flux (from the second target 116) traveling in a second direction. The first and second directions are both downward and inward (angled toward each other), for example, toward a center of the deposition chamber 110. Each target is coupled to a power source (e.g., power source 135, or a first power source, and power source 136, or a second power source). In some embodiments, the targets 112, 116 are each coupled to a common power source.

A selectively sealable aperture 122, or opening, couples the interior volumes of the linear PVD source 102 and the deposition chamber 110 to selectively allow or prevent the stream 108 of material flux to pass from the housing into the deposition chamber 110, and onto the substrate 106. The selectively sealable aperture 122 includes at least two movable shields that are independently movable and configured to control the size and location of the selectively sealable aperture 122. As depicted in FIG. 1, a first movable shield 124 and a second movable shield 126 are shown. Each of the first and second movable shields 124, 126 have facing edges that interface to form a seal when disposed adjacent to each other. For example, each of the first and second movable shields 124, 126 can have linear facing edges. Each of the first and second movable shields 124, 126 can move independently and linearly in order to control the size and position of the selectively sealable aperture 122 between the first and second movable shields 124, 126. Additionally, one or more cooling channels can be provided in each of the movable shields 124, 126 and configured to provide cooling water to the movable shields 124, 126 to maintain a relatively constant temperature at the movable shields 124, 126 during operation.

As discussed in more detail below, the position of the selectively sealable aperture 122 with respect to the target 112 as well as the dimensions of the selectively sealable aperture 122 can be selected or controlled to control the shape and size of the stream 108 of material flux passing though the selectively sealable aperture 122 and into the deposition chamber 110. For example, the length of the selectively sealable aperture 122 is wide enough to allow the stream 108 of material flux to be wider than the substrate 106. In addition, the width of the selectively sealable aperture 122 may be controlled to provide an even deposition rate along the length of the selectively sealable aperture 122 (e.g., a wider opening may provide greater deposition uniformity, while a narrower opening may provide increased control over the angle of impingement of the stream 108 of material flux on the substrate 106). In some embodiments, a plurality of magnets (not shown) may be positioned proximate the target 112 to control the position of the plasma with respect to the target 112 during processing. The deposition process can be tuned by controlling the plasma position (e.g., via the magnet position), and the size and relative position of the selectively sealable aperture 122.

In some embodiments a collimator can be provided between the target and the selectively sealable aperture 122 in the path of the stream 108 of material flux. For example, in FIG. 1, a first collimator 120 is shown in phantom between the first target 112 and the selectively sealable aperture 122. A second collimator 120 is shown in phantom between the second target 116 and the selectively sealable aperture 122. The collimators 120 can be configured to limit the angle of travel of particles in the stream 108 of material flux in at least one dimension. For example, in some embodiments, the collimators 120 can limit the lateral angle of travel of particles along the width of the stream 108 of material flux (e.g., into and out of the plane of the paper in FIG. 1). Alternatively or in combination, the collimators 120 can limit the angle of travel of particles in a direction perpendicular to the width of the stream 108 of material flux (e.g., within the plane of the paper in FIG. 1).

The housing of the linear PVD source 102 can include a liner of suitable material to retain particles deposited on the liner to reduce or eliminate particulate contamination on the substrate 106. The liner can be removable to facilitate cleaning or replacement. Similarly, a liner can be provided to some or all of the deposition chamber 110, for example, at least proximate the selectively sealable aperture 122. The housing of the linear PVD source 102 and the deposition chamber 110 are typically grounded.

In the embodiment depicted in FIG. 1 the linear PVD source 102 is stationary and the substrate support 104 is configured to move linearly. The substrate 106 may be moved linearly along an axis parallel to a plane of the support surface of the substrate support 104 (e.g., parallel to the plane of the substrate surface). For example, the substrate support 104 is coupled to a shaft 127 that can move linearly back and forth (e.g., left and right as shown on the page in FIG. 1) sufficiently to allow the stream 108 of material flux to impinge upon desired portions of the substrate 106, such as the entire substrate 104. A position control mechanism 128, such as an actuator, motor, drive, robot, or the like, controls the position of the substrate support 104, for example, via the shaft 127.

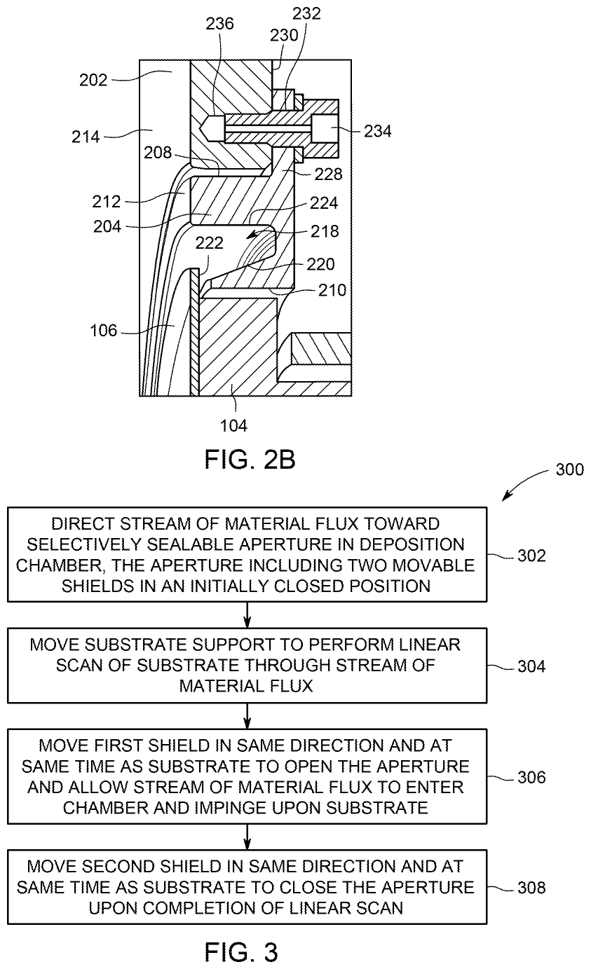

FIGS. 2A-2B respectively depict schematic top and isometric cross-sectional views of a substrate support (such as the substrate support 104 discussed above) and an exemplary deposition structure of an apparatus for physical vapor deposition in accordance with at least some embodiments of the present disclosure. FIG. 2B is an isometric cross-sectional view of the substrate support and deposition structure taken along line I-I in FIG. 2A.

As shown in FIGS. 2A-2B, a deposition structure 202 may be disposed around the substrate 106 and the substrate support 104 within the deposition chamber (e.g., 110 described above with respect to FIG. 1). For example, the deposition structure may be coupled to the substrate support 104. In some embodiments, the deposition structure 202 and a front surface of the substrate 106 form a common planar surface. The deposition structure 202 reduces deposits or particles from accumulating on the edge and backside of the substrate 106 during the scanning of the substrate 106. Furthermore, use of the deposition structure 202 reduces deposits or particles from accumulating on the substrate support 104 and hardware and equipment in the vicinity of the substrate support 104. In some embodiments, a voltage source (not shown) may be coupled to a portion of the deposition structure 202 to apply a charge to a portion of the deposition structure 202. In some embodiments, the voltage source may be used to apply a voltage or charge to a removable structure 204 associated with the deposition structure 202. Although the stream of material flux comprises mostly neutrals, applying a charge to the portion of the deposition structure 202 or the removable structure 204 may further reduce deposits or particles that accumulate on the edge and backside of the substrate during the scanning of the substrate 106 due to any ionized particles.

In some embodiments, the removable structure 204 can be disposed in an opening 206 of the deposition structure 202. The removable structure 204 can have a shape that corresponds to the substrate 106. For example, in embodiments where the substrate 106 is a circular substrate, such as a semiconductor wafer, the removable structure 204 is a removable ring structure. As depicted in FIGS. 2A-2B, the substrate 106 is exposed through the opening 206.

The removable structure 204 has an outside edge surface 208 and an inside edge surface 210. A circumference of the inside edge surface 210 is greater than a circumference of the substrate support 104. Furthermore, in some embodiments, the removable structure 204 has an exterior surface 212 aligned with a front surface 214 of the deposition structure 202. Furthermore, in some embodiments, a front surface 216 of the substrate 106 may be aligned with the front surface 214 of the deposition structure 202 and the exterior surface 212 of the removable structure 204. Therefore, in some embodiments, the exterior surface 212 of the removable structure 204, the front surface 214 of the deposition structure 202, and the front surface 216 of the substrate 106 form a planar surface. In some embodiments, the exterior surface 212 is not aligned with the front surface 214 of the deposition structure 202 and/or the front surface 216 of the substrate 106.

As depicted in FIG. 2B, the removable structure 204 includes a groove 218. The groove 218 may be formed in at least a portion of a circumference of the removable structure 204. In some embodiments, the groove 218 is formed in the entire circumference of the removable structure 204. The groove 218 may include an angled surface 220 functional to direct the particles associated with the stream 108 of material flux away from a backside 222 of the substrate 106. Moreover, the angled surface 220 is functional to direct particles associated with the stream 108 of material flux away from the substrate support 104. In some embodiments, particles associated with the stream 108 of material flux may be directed by the angled surface 220 toward a surface 224 associated with the groove 218. The groove 218 may be formed having a shallower or deeper depth than shown in FIG. 2B. Furthermore, while the surface 224 is illustrated as being straight, the surface 224 may alternatively be formed at an angle similar to the angled surface 220.

The removable structure 204 can include a ledge 228. The ledge 228 may be in contact with a backside 230 of the deposition structure 202. In some embodiments, the ledge 228 is removably press fit against the deposition structure 202, on the backside 230 of the deposition structure 202.

In some embodiments, the ledge 228 is coupled to the deposition structure 202, on the backside 230 of the deposition structure 202. For example, the removable structure 204 may include one or more through holes 232. In some embodiments, a plurality of through holes 232 are disposed in the ledge 228. The plurality of through holes 232 may receive a retainer element 234, such as a fastener, screw, or the like. Each of the retainer elements 234 may be received by a hole 236 in the deposition structure 202. Therefore, the deposition structure 202 may include a plurality of the holes 236. In another embodiment, the holes 236 may be through holes so that the retainer elements 234 may be inserted from the front surface 214 of the deposition structure 202 and retainably attached to the ledge 228 using a nut, fastener or threads.

The deposition structure 202 having the removable structure 204 is advantageously straightforward to maintain. Specifically, advantageously, rather than removing the entire deposition structure when preventive maintenance is required, the removable structure 204 can be removed to complete the required preventative maintenance. Furthermore, because the deposition structure 202 and the removable structure 204 pieces advantageously provide a modular unit, the costs associated with maintaining and replacing the modular unit may be advantageously reduced compared to maintaining and replacing conventional deposition structures formed as one contiguous unit. In addition, advantageously, removable structures (e.g., removable rings) may be made from different materials compared to the remainder of the substrate plan structure. For example, use of particular material types for the removable rings may advantageously mitigate accumulation of deposits and particles on the edge of the substrate 106.

Returning to FIG. 1, the substrate support 104 is movable at least between a first position, closest to a first side of the deposition chamber 110, and a second position, closest to a second side of the deposition chamber 110 opposite the first side. The first position is configured such that, in operation, the stream 108 of material flux is proximate a first side of the substrate 106. In the first position, the stream 108 of material flux can either miss the substrate 106 or can impinge upon at least the working surface of the substrate 106 along the first side of the substrate 106. The second position is configured such that, in operation, the stream 108 of material flux is proximate a second side of the substrate 106, opposite the first side. In the second position, the stream 108 of material flux can either miss the substrate 106 or can impinge upon at least the working surface of the substrate 106 along the second side of the substrate 106. The first and second positions are configured such that motion between the two positions will cause the stream 108 of material flux to move across the substrate 106 from the first side to the second side, thus impinging upon the entire working surface of the substrate over the course of a single scan from the first position to the second position (or from the second position to the first position).

The deposition chamber 110, and in turn the overall apparatus 100, is sized to accommodate the movement of the substrate support 104 and the deposition structure 202 within the deposition chamber 110. However, in combination with the control of the size and position of the opening of the selectively sealable aperture 122, the movement of the substrate support 104 between the first and second positions can be advantageously minimized to reduce the size or footprint of the deposition chamber 110 (and overall of the apparatus 100). For example, as noted above, the chamber footprint can be about 30-50% smaller in the dimension that is aligned to the scan motion of the substrate support.

Optionally, the substrate support 104 can also be configured to rotate within the plane of the support surface, such that the substrate 106 disposed on the substrate support 104 can be rotated. A rotation control mechanism, such as an actuator, motor, drive, or the like, controls the rotation of the substrate support 104 independent of the linear position of the substrate support 104. Accordingly, the substrate support 104 can be rotated while the substrate support 104 is also moving linearly through the stream 108 of material flux during operation. Alternatively, the substrate support 104 can be rotated between linear scans of the substrate support 104 through the stream 108 of material flux during operation (e.g., the substrate support 104 can be moved linearly without rotation, and rotated while not moving linearly).

In addition, the substrate support 104 can move to a position for loading and unloading of substrates into and out of the deposition chamber 110. For example, a selectively sealable opening 130, such as a slit valve, is provided to load and unload substrates from the deposition chamber 110. In some embodiments, a transfer chamber (not shown), such as a load lock, may be coupled to the deposition chamber 110 via the opening 130. A substrate transfer robot, or other similar suitable substrate transfer device, can be disposed within the transfer chamber to move substrates into and out of the deposition chamber (and onto and off of the substrate support 104). Lift pins or other suitable mechanisms may be provided to lift the substrate 106 from the substrate support 104 when in the loading and unloading position.

Depending upon the configuration of the substrate support 104, and in particular of the support surface of the substrate support 104 (e.g., vertical, horizontal, or angled), the substrate support 104 may be configured appropriately to retain the substrate 106 during processing. For example, in some embodiments, the substrate 106 may rest on the substrate support 104 via gravity. In some embodiments, the substrate 106 may be secured onto the substrate support 104, for example, via a vacuum chuck, an electrostatic chuck, mechanical clamps, or the like. Substrate guides and alignment structures may also be provided to improve alignment and retention of the substrate 106 on the substrate support 104.

The apparatus disclosed herein can be implemented in numerous ways, and only certain exemplary non-limiting embodiments are depicted in FIG. 1 through FIG. 2B. While the Figures discuss particular exemplary features of the apparatus 100, variations of these features may be made in keeping with the teachings provided herein. In addition, although the Figures may show an apparatus having a particular orientation, such orientations are examples and not limiting of the disclosure. For example, any configuration can be rotated or oriented differently than as shown on the page.

The methods and embodiments disclosed herein advantageously enable deposition of materials with a shaped profile, or in particular, with an asymmetric profile with respect to a given feature on a substrate, while maintaining overall deposition and shape uniformity across all features on a substrate.

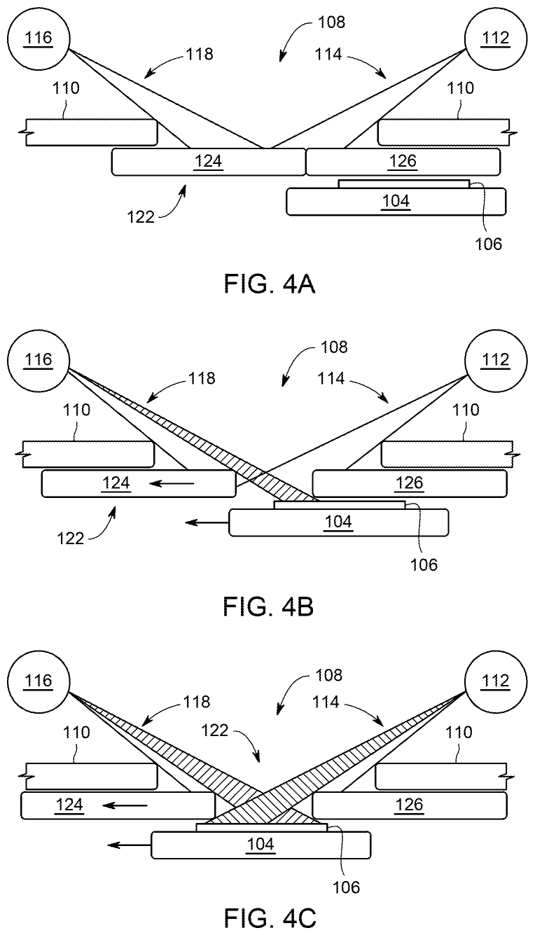

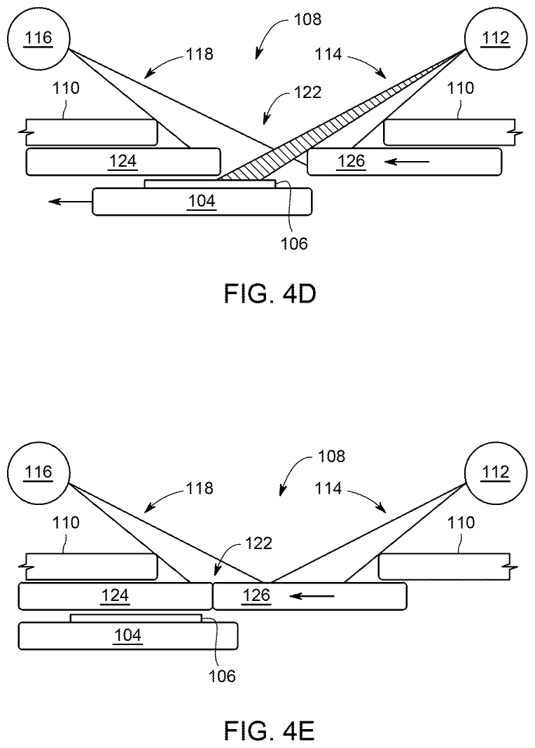

For example, FIG. 3 provides a flow chart of a method 300 for depositing a layer of material on a substrate in accordance with at least some embodiments of the present disclosure. FIGS. 4A-4E respectively depict stages of operation of the apparatus during the method of FIG. 3 in accordance with at least some embodiments of the present disclosure. The method 300 may be performed using a system similar to the apparatus 100 discussed above with respect to FIG. 1.

The method 300 generally begins at 302 where the stream 108 of material flux is directed toward a selectively sealable aperture 122 in the deposition chamber 110. As discussed above with respect to FIG. 1, the selectively sealable aperture 122 includes two movable shields. Initially, the two movable shields are in a closed position, as depicted in FIG. 4A. More specifically, the two movable shields are positioned such that the mouth of the selectively sealable aperture 122 is in a closed position on the same side of the process chamber as the substrate support 104. For example, in the orientation shown in FIG. 4A, the substrate support 104 is all the way to the right of the drawing, and the mouth of the selectively sealable aperture 122 is in a closed position to the left of the substrate 106, but also on the right side of the process chamber.

Next, at 304, the substrate support 104 is moved to perform a linear scan of the substrate 106 disposed on the substrate support 104. The substrate support 104 is moved completely through the stream 108 of material flux to deposit materials across an entire desired portion of the substrate 106, such as over the entire substrate 106. During the linear scan, the two movable shields provide a movable opening corresponding to the position of the substrate 106 to facilitate the deposition while limiting the size and position of the stream 108 of material flux impinging upon the substrate support 104 (and substrate 106 disposed thereon). Thus, the two movable shields advantageously limit the overall size of the stream 108 of material flux, which in turn facilitates reduction in the size of the process kit shield needed to protect the substrate support 104 and deposition chamber interior from unwanted deposition on chamber surfaces.

For example, initially, and as shown in FIG. 4A, a first shield 124 and a second shield 126 of the two movable shields are each in a first position corresponding to the closed position on the right side of the Figure. The first position may be a physical maximum amount of travel in a given direction (e.g., to the right in the orientation of FIG. 4A) or may be a controlled position based upon configuration of a controller 132 (FIG. 1) that controls operation of the apparatus.

Next, at 306 the first shield 124 of the two movable shields is moved in the same direction and at the same time as the substrate 106 to open the selectively sealable aperture 122 and allow the stream 108 of material flux to enter the deposition chamber and impinge upon the substrate 106, as depicted in FIG. 4B. In some embodiments, the movement of the first shield 124 can continue until the first shield 124 reaches a second position corresponding to a maximum selectively sealable aperture 122 size.

At 308, the second shield 126 of the two movable shields is moved in the same direction and at the same time as the substrate 106 to close the selectively sealable aperture 122 upon completion of the linear scan. The movement of the second shield 126 continues until the second shield 126 reaches a second position corresponding to providing the selectively sealable aperture 122 in a closed position on an opposite side of the apparatus. For example, in the orientation of FIGS. 4A-E, the closed position at the completion of the linear scan is on the left side of the apparatus, but to the right of the substrate 106.

In some embodiments, and as shown in FIG. 4D, the second shield 126 can begin movement after the first shield 124 is in the second position (e.g., the selectively sealable aperture 122 is at the maximum opening size). As shown in FIG. 4E, the movement of the second shield 126 continues in the same direction along with the substrate support 104 until the second shield 126 reaches the second position and the selectively sealable aperture 122 is closed.

In some embodiments, the second shield 126 can begin movement prior to the first shield 124 reaching the second position and ceasing movement. In such embodiments, the selectively sealable aperture 122 reaches maximum opening size and moves, along with the movement of the first and second shields 124, 126, until the first shield 124 reaches the second position and ceases movement. Then, the selectively sealable aperture 122 begins closing as the second shield 126 continues moving toward the second position. As in the prior embodiments, the selectively sealable aperture 122 is fully closed upon the second shield 126 reaching the second position.

In addition to control of the selectively sealable aperture 122 as discussed above, in embodiments of a PVD apparatus as disclosed herein, the general angle of incidence of the stream 108 of material flux can be controlled or selected to facilitate a desired deposition profile of material on the substrate 106. In addition, the general shape of the stream 108 of material flux can be controlled or selected to control the deposition profile of material deposited on the substrate 106. In some embodiments, material can be deposited on a top surface of the substrate 106 and a first sidewall of a feature on the substrate 106. In some embodiments, depending upon the deposition angle, material can further be deposited on a bottom surface of the feature. In some embodiments, depending upon the deposition angle, material can further be deposited on an opposing sidewall surface of the feature, with greater deposition on a first sidewall as compared to the opposing sidewall of the feature.

The substrate support 104 can be moved linearly from the first position (for example, where the stream 108 of material flux is proximate a first side of the substrate 106), through the stream 108 of material flux to the second position (for example, where the stream 108 of material flux is proximate a second side of the substrate 106 opposite the first side). The amount of deposition of material on the substrate 106 depends upon the deposition rate and the rate of speed of the linear movement of the substrate 106 through the stream 108 of material flux. The substrate 106 can pass through the stream 108 of material flux once (e.g., move from the first position to the second position once) or multiple times (e.g., move from the first position to the second position, then move from the second position to the first position, etc.) in order to deposit a desired thickness of material on the substrate 106. Optionally, the substrate 106 can be rotated between passes (e.g., after reaching the first position or the second position at the end of linear movement) or while passing through the stream 108 of material flux (e.g., at the same time as the linear movement from the first position to the second position).

In embodiments where two streams 114, 118 of material flux are provided, the streams can be alternated or provided simultaneously. In addition, the orientation of the substrate 106 can be rotationally fixed or variable. For example, in some embodiments, the two streams 114, 118 of material flux can alternately provide the same material or different materials to be deposited asymmetrically on the substrate 106. The substrate 106 can be rotationally fixed while the first stream (e.g., 114) of material flux is provided in a first pass through the first stream 114 of material flux. The substrate 106 can then be rotated 180 degrees and subsequently be rotationally fixed while the second stream 118 of material flux is provided in a first pass through the second stream 118 of material flux. If desired, after completion of the first pass through the second stream 118 of material flux, the substrate 106 can again be rotated 180 degrees and then held rotationally fixed in a second pass through the first stream 114 of material flux. The rotation of the substrate 106 and passes through either the first or the second streams 114, 118 of material flux can continue until a desired thickness of material is provided. In cases where the first and second streams 114, 118 of material flux provide different materials to be deposited, the rate of movement of the substrate support 104 can be the same or different when passing through the first stream 114 of material flux as compared to passing through the second stream 118 of material flux.

In some embodiments, the substrate 106 can be rotated continuously while passing through the first or the second streams 114, 118 of material flux (e.g., at the same time as the linear movement from the first position to the second position or from the second position to the first position).

While the foregoing is directed to embodiments of the present disclosure, other and further embodiments of the disclosure may be devised without departing from the basic scope thereof.

1. An apparatus for physical vapor deposition (PVD), comprising:
a linear PVD source to provide a stream of material flux comprising material to be deposited on a substrate;
a substrate support having a support surface to support the substrate at a non-perpendicular angle to the stream of material flux, wherein the substrate support and linear PVD source are movable with respect to each other along an axis that is parallel to a plane of the support surface of the substrate support sufficiently to cause the stream of material flux to move completely over a surface of the substrate disposed on the substrate support during operation; and
a selectively sealable aperture disposed between the linear PVD source and the substrate support, the selectively sealable aperture including two movable shields that are independently movable and configured to control a size and location of the selectively sealable aperture.

2. The apparatus of claim 1, wherein the substrate support is configured to rotate the substrate within the plane of the substrate.

3. The apparatus of claim 1, wherein the selectively sealable aperture couples interior volumes of the linear PVD source and a deposition chamber to which the linear PVD source is coupled to selectively at least one of allow or prevent the stream of material flux to pass from a housing of the linear PVD source into the deposition chamber and onto the substrate.

4. The apparatus of claim 1, wherein the two movable shields comprise a first and second movable shield, and
wherein each of the first and second movable shields have corresponding facing edges that interface to form a seal when disposed adjacent to each other.

5. The apparatus of claim 4, wherein the facing edges of each of the first and second movable shields are linear facing edges.

6. An apparatus for physical vapor deposition (PVD), comprising:
a linear PVD source having a first target and a second target, each configured to provide corresponding first and second streams of material flux comprising material to be deposited on a substrate;
a substrate support having a support surface to support the substrate at a non-perpendicular angle to the first and second streams of material flux, wherein the substrate support and the linear PVD source are movable with respect to each other along an axis that is parallel to a plane of the support surface of the substrate support sufficiently to cause the first and second streams of material flux to move completely over a surface of the substrate disposed on the substrate support during operation; and
a selectively sealable aperture disposed between the linear PVD source and the substrate support, the selectively sealable aperture including two movable shields that are independently movable and configured to control a size and location of the selectively sealable aperture.

7. The apparatus of claim 6, wherein the substrate support is rotated continuously while passing through at least one of the first or the second streams of material flux as at least one of the two movable shields are moved.

8. The apparatus of claim 6, wherein the first and second streams of material flux provided from the first and second targets is one of a same material or different material and is one of alternated or provided simultaneously.

9. The apparatus of claim 8, wherein when the first and second streams of material flux provide different materials to be deposited on the substrate, a rate of movement of the substrate support can be one of a same or different when passing through the first stream of material flux as compared to passing through the second stream of material flux.

10. A method for depositing material on a substrate, comprising:
directing a stream of material flux toward a selectively sealable aperture in a deposition chamber, wherein the selectively sealable aperture includes two movable shields in an initially closed position;
moving a substrate support within the deposition chamber to perform a linear scan of the substrate disposed on the substrate support through the stream of material flux;
moving a first shield of the two movable shields in a same direction and at a same time as the substrate to open the selectively sealable aperture and allow the stream of material flux to enter the deposition chamber and impinge upon the substrate; and
moving a second shield of the two movable shields in the same direction and at the same time as the substrate to close the selectively sealable aperture upon completion of the linear scan.

11. The method of claim 10, further comprising, prior to moving the first shield and the second shield, positioning the first shield and the second shield such that a mouth of the selectively sealable aperture is in a closed position on a same side of the deposition chamber as the substrate support.

12. The method of claim 10, wherein moving the first shield comprises moving the first shield so that a length of the selectively sealable aperture is wide enough to allow the stream of material flux to be wider than the substrate.

13. The method of claim 10, further comprising moving at least one of the first shield or the second shield to control a width of the selectively sealable aperture to provide at least one of an even deposition rate along a length of the selectively sealable aperture or to provide increased control over an angle of impingement of the stream of material flux on the substrate.

14. The method of claim 10, wherein moving the first shield comprises moving the first shield from a first position, corresponding to at least one of a physical maximum amount of travel in a given direction of the first shield or a controlled position based upon configuration of a controller that controls operation of the deposition chamber, to a second position, corresponding to a maximum selectively sealable aperture size.

15. The method of claim 10, wherein moving the second shield comprises moving the second shield after the first shield reaches the second position and continuing moving the second shield until the selectively sealable aperture is closed.

16. The method of claim 10, wherein moving the second shield comprises moving the second shield prior to the first shield reaching the second position and ceasing movement and continuing moving the second shield until the selectively sealable aperture is closed.

17. The method of claim 10, further comprising providing the first shield and second shield with linear facing edges.

18. The method of claim 10, wherein directing the stream of material flux toward the selectively sealable aperture in the deposition chamber comprises directing first and second streams of material flux toward the selectively sealable aperture in the deposition chamber.

19. The method of claim 18, further comprising continuously rotating the substrate support while passing the substrate support through at least one of the first or the second streams of material flux as at least one of the first shield and second shield are moved.

20. The method of claim 18, wherein directing the first and second streams of material flux toward the selectively sealable aperture in the deposition chamber comprises providing that a material of the first and second streams of material flux is one of a same material or different material.
